(19) United States
(12) Patent Application Publication
(10) Pub. No.: US 2018/0342684 A1
(43) Pub. Date: Nov. 29, 2018

(54) LIGHT-EMITTING METAL COMPLEX AND DEVICE

(71) Applicants: Cambridge Display Technology Limited, Godmanchester (GB); Sumitomo Chemical Company Limited, Tokyo (JP)

(72) Inventors: Annette Steudel, Dresden (DE); Florence Bourcet, Godmanchester (GB)

(21) Appl. No.: 15/514,164

(22) PCT Filed: Sep. 25, 2015
(86) PCT No.: PCT/GB2015/052795

§ 371 Date: Mar. 24, 2017

(30) Foreign Application Priority Data
Sep. 25, 2014 (GB) 1416950.2

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

A phosphorescent metal complex comprising at least one ligand substituted with a group of formula (IIIa), (IIIb) or (IIIc): wherein Y is selected from O, S, a substituted carbon atom; and a substituted silicon atom; Z in each occurrence is independently selected from N and P; R⁴ independently in each occurrence is a substituent; R⁵ independently in each occurrence is H or a substituent; x independently in each occurrence is 0, 1, 2 or 3; y and z in each occurrence are independently 0, 1, 2, 3 or 4. The group of formula (IIIa), (Mb) or (IIIc) may be directly bound to the ligand or spaced apart therefrom by a spacer group. The phosphorescent metal complex may be used as a light-emitting material in an organic light-emitting device.

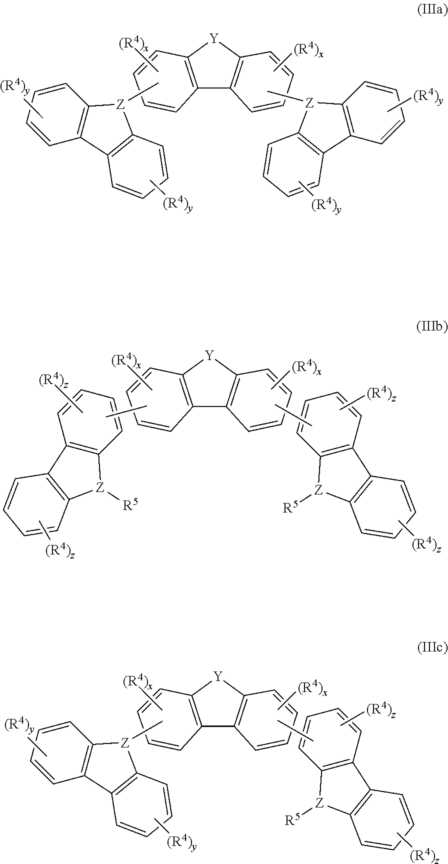

### BACKGROUND

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

Sook et al, J. Mater. Chem., 2011, 21, 14604 discloses a composition of a phosphorescent material and a host material selected from DBT1, DBT2 and DBT3:

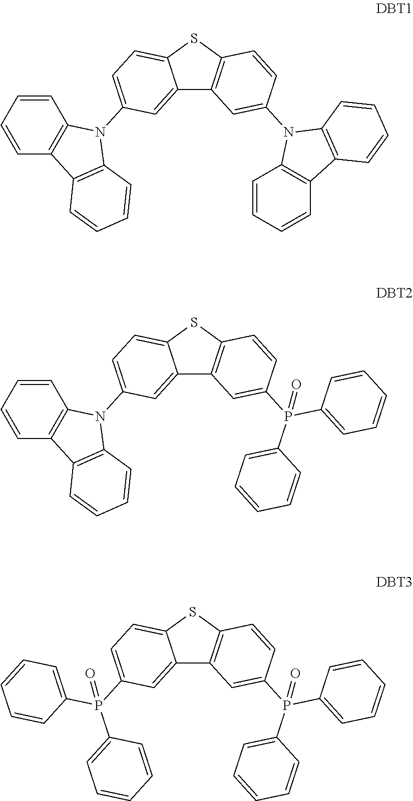 [SMILES: c1ccc2c(c1)c1ccccc1n2-c1ccc2sc3ccc(-n4c5ccccc5c5ccccc54)cc3c2c1 ; O=P(c1ccccc1)(c1ccccc1)c1ccc2sc3ccc(-n4c5ccccc5c5ccccc54)cc3c2c1 ; O=P(c1ccccc1)(c1ccccc1)c1ccc2sc3ccc(P(=O)(c4ccccc4)c4ccccc4)cc3c2c1]

WO 03/079736 discloses an organometallic dendrimer having a core of a metal complex substituted with charge-transporting dendrons containing nitrogen atoms. An OLED having a light-emitting layer consisting of the organometallic dendrimer is disclosed. WO 03/079736 discloses a dendron bound to a phenylpyridyl coordinating group illustrated below, which is used to form a green-emitting iridium organometallic dendrimer.

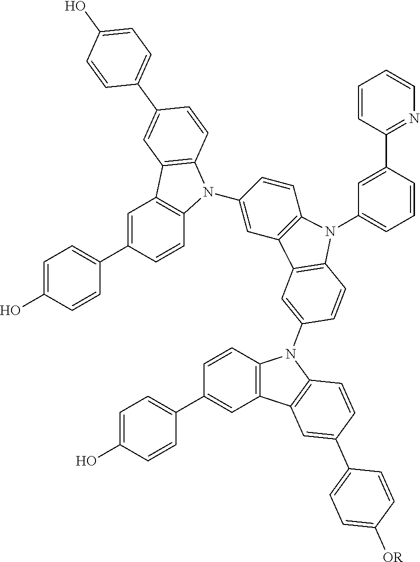

US 2013/049576 discloses the following compound within a list of phosphorescent complexes:

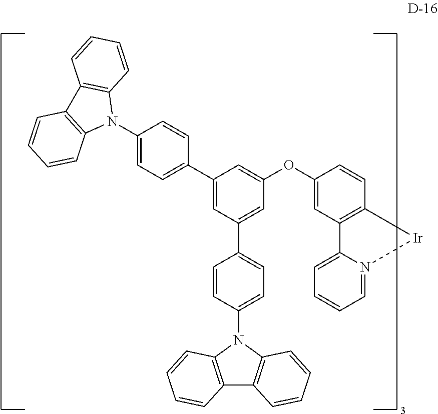

JP2011008991 discloses a metal complex having the following structure within a list of metal complexes:

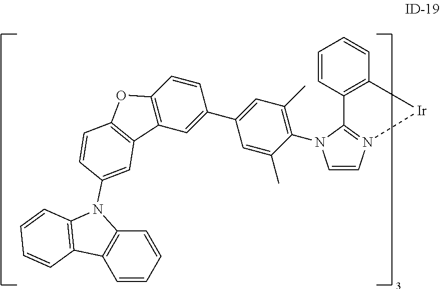

### SUMMARY OF THE INVENTION

In a first aspect the invention provides a phosphorescent metal complex of formula (I):

ML¹ₙL²ₘ (I)

wherein:
M is a transition metal;
L¹ is a ligand substituted with at least one group of formula (II):

*-(Sp)ₐ-(X)_{b} (II)

wherein Sp is a spacer group; a is 0 or 1; b is 1 if a is 0 and b is at least 1 if a is 1; and X independently in each occurrence is a group of formula (IIIa), (IIIb) or (IIIc):

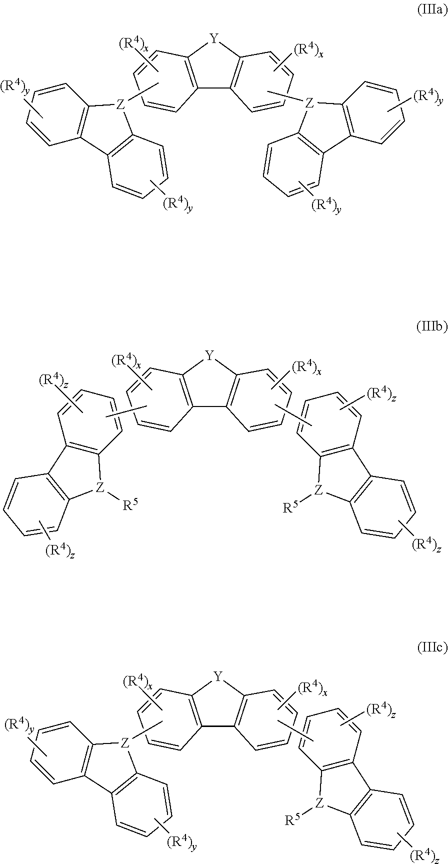

wherein Y is selected from O, S, a substituted carbon atom; and a substituted silicon atom; Z in each occurrence is independently selected from N and P; R⁴ independently in each occurrence is a substituent; R⁵ independently in each occurrence is H or a substituent; x independently in each occurrence is 0, 1, 2 or 3; y in each occurrence is independently 0, 1, 2, 3 or 4; and z in each occurrence is independently 0, 1, 2, 3 or 4;
   L² independently in each occurrence is a ligand that may be unsubstituted or substituted with one or more substituents;
   n is at least 1; and
   m is 0 or a positive integer.

In a second aspect the invention provides an organic light-emitting device comprising an anode, a cathode and a light-emitting layer between the anode and the cathode wherein the light-emitting layer comprises a phosphorescent metal complex according to the first aspect.

In a third aspect the invention provides a formulation comprising a phosphorescent metal complex according to the first aspect and at least one solvent.

In a fourth aspect the invention provides a method of forming an organic light-emitting device according to the second aspect wherein the light-emitting layer is formed by depositing the formulation according to the third aspect onto the hole-transporting layer and evaporating the solvent.

In a fifth aspect the invention provides an organic light-emitting device comprising an anode, a cathode and a light-emitting layer between the anode and the cathode, wherein the light-emitting layer consists essentially of a phosphorescent light-emitting material comprising a hole-transporting light-emitting metal complex and an electron-transporting substituent bound to the light-emitting metal complex.

The phosphorescent light-emitting material of the fifth aspect may be a material as described in the first aspect. The device of the fifth aspect may be as described with reference to the second aspect and may be formed as described with reference to the fourth aspect.

### DESCRIPTION OF THE DRAWINGS

The invention will now be described in more detail with reference to the drawings in which:

FIG. 1 illustrates schematically an OLED according to an embodiment of the invention;

FIG. 2 is a graph of current density vs. voltage for two devices according to embodiments of the invention and two comparative devices;

FIG. 3 is a graph of external quantum efficiency vs. voltage for two devices according to embodiments of the invention and two comparative devices; and

FIG. 4 is a graph of luminance vs. time for two devices according to embodiments of the invention and two comparative devices.

### DETAILED DESCRIPTION OF THE INVENTION

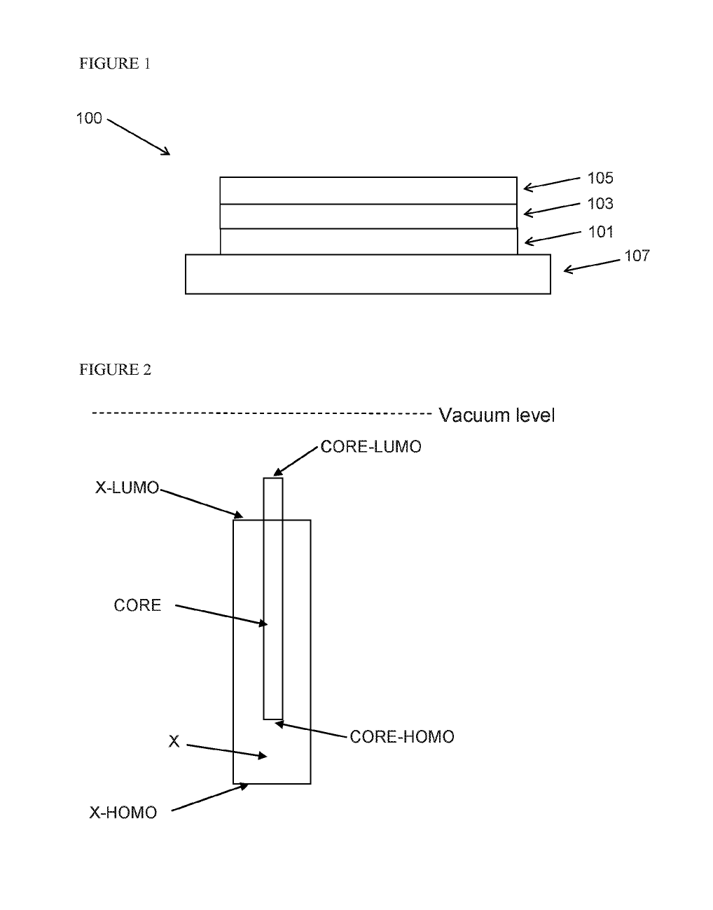

FIG. 1 illustrates an OLED 100 according to an embodiment of the invention comprising an anode 101, a cathode 105 and a light-emitting layer 103 between the anode and cathode. The device 100 is supported on a substrate 107, for example a glass or plastic substrate.

Light-emitting layer 103 may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

Light-emitting layer 103 contains a phosphorescent compound of formula (I). The light-emitting layer 103 may consist essentially of the compound of formula (I) or it may contain one or more materials, for example one or more further light-emitting materials. The compound of formula (I) has charge-transporting substituent X of formula (II) bound thereto and so the presence of any further charge-transporting host material in layer 103 may be unnecessary. Accordingly, light-emitting layer 103 preferably consists essentially of the compound of formula (I) or consists essentially of the compound of formula (I) and one or more further light-emitting materials.

One or more further layers may be provided between the anode 101 and cathode 105, for example hole-transporting layers, electron transporting layers, hole blocking layers and electron blocking layers.

Preferred device structures include:

Anode/Hole-injection layer/Light-emitting layer/Cathode
Anode/Hole transporting layer/Light-emitting layer/Cathode
Anode/Hole-injection layer/Hole-transporting layer/Light-emitting layer/Cathode
Anode/Hole-injection layer/Hole-transporting layer/Light-emitting layer/Electron-transporting layer/Cathode.

Preferably, at least one of a hole-transporting layer and hole injection layer is present. Preferably, both a hole injection layer and hole-transporting layer are present.

In operation, substantially all light emitted from the device may be light emitted from the phosphorescent compound of formula (I), or one or more further fluorescent or phosphorescent light-emitting materials may be present.

In embodiments of the invention, substantially all light emitted from the device is from the compound of formula (I). In other embodiments of the invention, the device may contain at least one further light-emitting material in layer 103 or in a separate light-emitting layer. The further light emitting material or materials may be fluorescent or phosphorescent light-emitting materials.

The OLED may be a white-emitting OLED. A white-emitting OLED may contain a single, white-emitting layer or may contain two or more layers that emit different colours which, in combination, produce white light. White light may be produced from a combination of red, green and blue light-emitting materials provided in a single light-emitting layer or distributed within two or more light-emitting layers.

The light emitted from a white-emitting OLED may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

The compound of formula (I) is preferably a blue phosphorescent compound. The photoluminescent spectrum of the phosphorescent compound of formula (I) may have a peak in the range of 420-490 nm, more preferably 420-480 nm.

If present in light-emitting layer 103 or in a separate layer, the one or more further light-emitting materials may be selected from green and red fluorescent or phosphorescent materials.

A green emitting material may have a photoluminescent spectrum with a peak in the range of more than 490 nm up to 580 nm, optionally more than 490 nm up to 540 nm.

A red emitting material may optionally have a peak in its photoluminescent spectrum of more than 580 nm up to 630 nm, optionally 585-625 nm.

If present, a charge-transporting layer adjacent to a phosphorescent light-emitting layer preferably contains a charge-transporting material having a T₁ excited state energy level that is no more than 0.1 eV lower than, preferably the same as or higher than, the T₁ excited state energy level of the phosphorescent compound of formula (I) in order to avoid quenching of triplet excitons migrating from the light-emitting layer into the charge-transporting layer.

Triplet energy levels as described anywhere herein may be as measured from the energy onset (energy at half of the peak intensity on the high energy side) of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

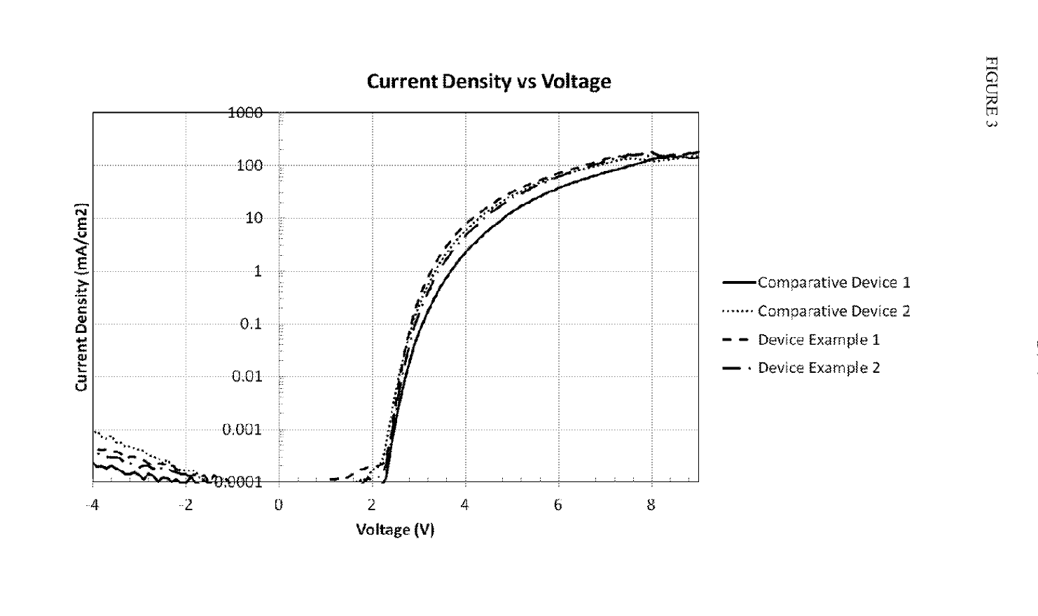

With reference to FIG. 2, the metal complex core of the compound of formula (I) (CORE) may have a HOMO level that is shallower (closer to vacuum) than the HOMO level of the substituent X, and a LUMO level that is shallower than the LUMO level of the substituent of formula X. Accordingly, hole-transport in the light-emitting layer 103 may be provided by the metal complex core of the compound of formula (I) and electron transport may be provided by the substituent X.

The metal complex core as described herein means the compound of formula (I) without any substituents of formula (II).

The substituent X of formula (IIIa), (IIIb) or (IIIc) may be bound directly to the metal complex core or may be spaced apart therefrom by spacer group Sp in the case where a of formula (I) is 1.

The spacer group Sp may limit or break conjugation between the group X and the ligand L¹. This may reduce or avoid red-shifting of the colour of emission of the compound of formula (I) as compared to a compound that is not substituted with the group X, or changes in the HOMO and/or LUMO levels of the metal complex core or the group X as a result of conjugation between the metal complex core and the group X.

Exemplary spacer groups Sp, where present, may have formula (IV):

(Ar¹)ₚ (IV)

wherein Ar¹ in each occurrence is independently an aryl or heteroaryl group that may be unsubstituted or substituted with one or more substituents and p is at least 1.

Preferably, each Ar¹ is phenyl.

One or more H atoms of Ar¹ may be replaced with D.

Preferably, each substituent of Ar¹, where present, is a substituent R².

R² may be selected from the group consisting of:
C₁₋₂₀ alkyl wherein one or more non-adjacent C atoms of the C₁₋₂₀ alkyl may be replaced with O, S, C═O or COO and one or more H atoms of the C₁₋₂₀ alkyl may be replaced with F; and
aryl or heteroaryl, preferably phenyl, that may be unsubstituted or substituted.

Preferably, R² in each occurrence is independently a C₁₋₄₀ hydrocarbyl group, more preferably C₁₋₂₀ alkyl; unsubstituted phenyl, or phenyl substituted with one or more C₁₋₂₀ alkyl groups.

Preferably, Sp has formula (IVa) or (IVb), (IVc) in the case where b of formula (I) is 1:

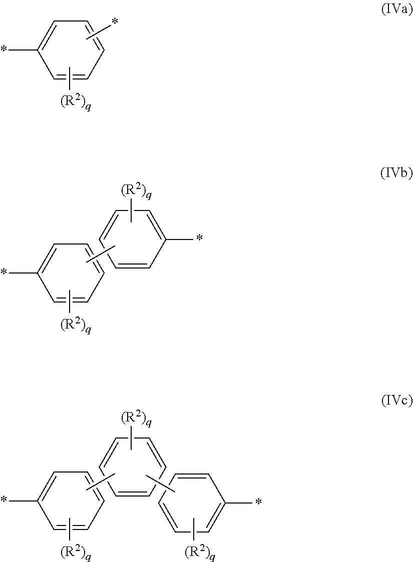

wherein R² in each occurrence is independently a substituent as described above, each q is independently 0, 1, 2, 3 or 4 and * represents a point of attachment of Sp to L¹ or to X. Preferably, at least one q is not 0. Preferably, at least one q 1 or 2.

Preferably, Sp has formula (IVd) in the case where b of formula (I) is 2:

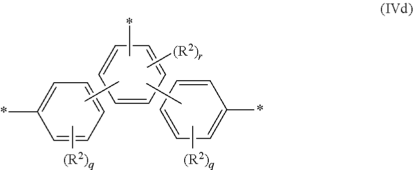

wherein R² in each occurrence is independently a substituent as described above, each q is independently 0, 1, 2, 3 or 4; r is 1, 2 or 3; and * represents a point of attachment of Sp to L¹ or to X.

Exemplary groups of formulae (IVa)-(IVd) are illustrated below:

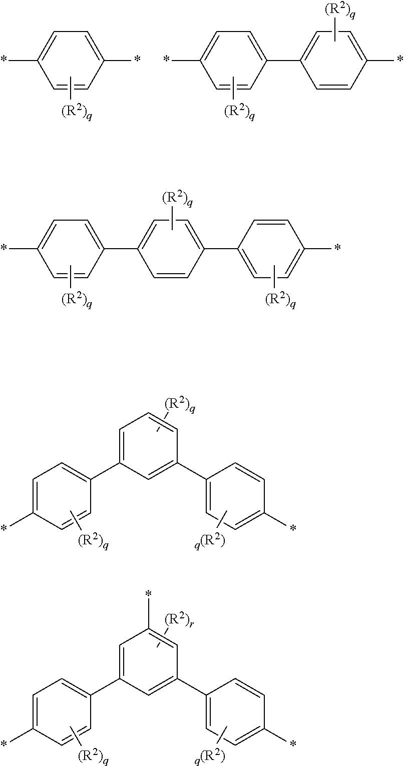

Preferably, at least one q and/or r is not 0.

Preferably, at least one q of formula (IVa), (IVb) or (IVc) is at least 1, optionally 1 or 2.

Preferably, r of formula (IVd) is 0 or 1.

One or both positions of Ar¹ adjacent to the bond between Ar¹ and L¹ may be substituted to created a twist between L¹ and Ar¹.

One or both positions of Ar¹ adjacent to the or each bond between Ar¹ and X may be substituted to created a twist between X and Ar¹.

If p is at least 2 then one or more positions adjacent to a bond between two groups Ar¹ may be substituted to create a twist between the two groups Ar¹.

The spacer group Sp may break conjugation between X and L¹. An exemplary conjugation-breaking spacer group Sp has formula (V):

*—(Ar¹)ₐ—(CR⁴₂)_{b}—(Ar₁)_{c}—* (V)

wherein Ar¹ in each occurrence is independently an aryl or heteroaryl group that may be unsubstituted or substituted with one or more substituents; a is at least 1; b is at least 1; c is at least 1; R⁴ in each occurrence is independently H or a substituent; and * represents a bond to L¹ or X.
Ar¹ may be as described with reference to formula (IV), and may be unsubstituted or substituted with one or more substituents R².
a and c are each preferably independently 1, 2 or 3.
b is preferably 1-10.
R⁴ is preferably H or C₁₋₅ alkyl.

The sp³ hybridised carbon atom of CR₄² breaks any conjugation path between L¹ and X.

The number of groups X in the compound of formula (I) is at least 1, and is optionally 2, 3, 4, 5, 6, 7, 8, 9 or 10, preferably 4-8.

The number of groups X bound to ligand L¹ is at least 1, and is optionally 2 or 3.

The group of formula (IIIa), (IIIb) or (IIIc) may be linked to L¹ or, if a spacer group Sp is present, linked to Sp through any ring atom of formula (IIIa), (IIIb) or (IIIc).

An aromatic carbon atom of formula (IIIa), (IIIb) or (IIIc) may be linked to L¹ or Sp by a covalent bond.

In the case where Y is a substituted carbon or silicon atom, the carbon or silicon atom may be linked to L¹ or Sp by a covalent bond.

If Y is bound to L¹ or Sp then Y may be selected from O, S, CR¹ and SiR¹ wherein R¹ independently in each occurrence is a substituent.

If Y is not bound to L¹ or Sp then Y may be selected from O, S, CR¹₂ and SiR¹₂ wherein R¹ independently in each occurrence is a substituent. Exemplary substituents R¹ are heteroaryl that may be unsubstituted or substituted with one or more substituents and C₁₋₄₀ hydrocarbyl, preferably C₁₋₂₀ alkyl; and unsubstituted or substituted aryl, optionally phenyl. Exemplary substituents of aryl or heteroaryl groups, if present, are C₁₋₂₀ alkyl groups.

Z in each occurrence is independently selected from N and P. Z is preferably N.

Preferably, each x of formula (IIIa), (IIIb) or (IIIc) is 0.

Preferably, each y of formula (IIIa) or (IIIc) is independently 0 or 1.

Preferably, z of formula (IIIb) or (IIIc) is independently 0 or 1.

Optionally, R⁴ of formula (IIIa), (IIIb) or (IIIc) is selected from the group consisting of:
C₁₋₂₀ alkyl wherein one or more non-adjacent C atoms of the C₁₋₂₀ alkyl may be replaced with O, S, C=0 or COO and one or more H atoms of the C₁₋₂₀ alkyl may be replaced with F; and
a group of formula —(Ar²)_{b} wherein each Ar² is independently an aryl or heteroaryl that may be unsubstituted or substituted with one or more substituents and b is at least 1, optionally 1, 2 or 3.

Optionally, —(Ar²)_{b} is phenyl that may be unsubstituted or substituted with one or more substituents.

Optionally, R⁵ of formula (IIIb) or (IIIc) is selected from H; C₁₋₁₀ alkyl; and phenyl that may be unsubstituted or substituted with one or more substituents. Optionally, the one or more substituents of phenyl are selected from C₁₋₁₀ alkyl groups. A preferred group of formula (IIIa) has formula (IIIa′):

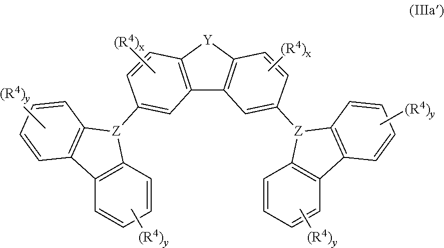

A preferred group of formula (IIIb) has formula (IIIb′)

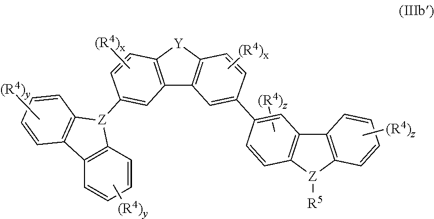

A preferred group of formula (IIIc) has formula (IIIc′):

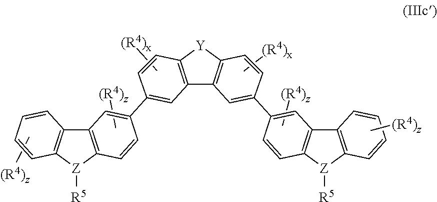

Exemplary groups of formula (IIIa) are illustrated below wherein the dotted line is a point of attachment to L¹ or, if present, Sp:

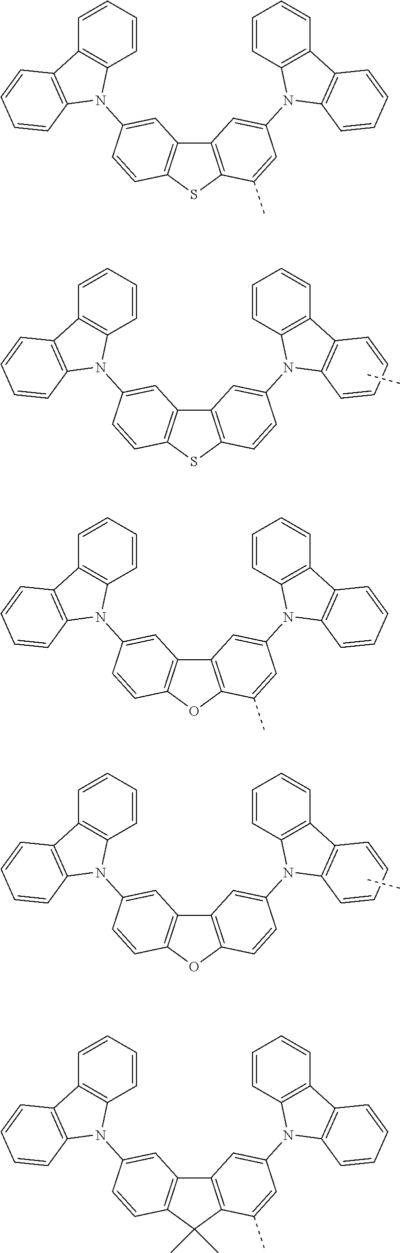

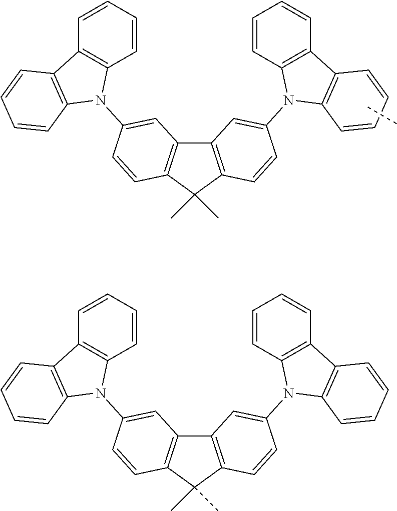

Examplary groups of formula (IIIc) are illustrated below wherein the dotted line is a point of attachment to L¹ or, if present, Sp:

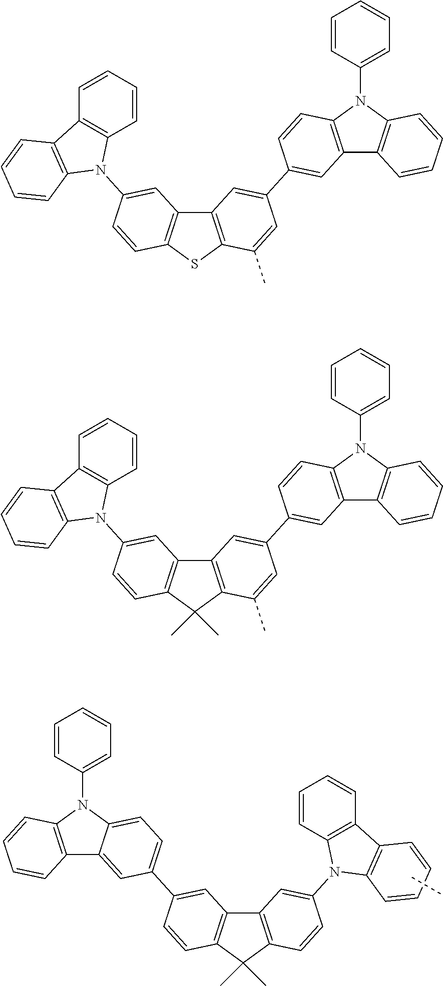

Heavy elements M induce strong spin-orbit coupling to allow rapid intersystem crossing and emission from triplet or higher states. Suitable heavy metals M include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹ and L² include carbon or nitrogen donors such as porphyrin or bidentate ligands of formula (XI):

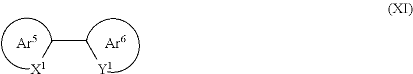

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together. Ligands wherein X¹ is carbon and Y¹ is nitrogen are preferred, in particular ligands in which Ar⁵ is a single ring or fused heteroaromatic of N and C atoms only, for example pyridyl or isoquinoline, and Ar⁶ is a single ring or fused aromatic, for example phenyl or naphthyl.

Ar⁵ and/or Ar⁶ of a ligand L¹ may be substituted with one or more groups of formula (II). The one or more groups of formula (II) may be the only substituents of Ar⁵ and/or Ar⁶, or L¹ may be substituted with one or more further substituents.

To achieve red emission, Ar⁵ may be selected from phenyl, fluorene, naphthyl. Ar⁶ may be selected from quinoline, isoquinoline, thiophene, benzothiophene.

To achieve green emission, Ar⁵ may be selected from phenyl or fluorene. Ar⁶ may be pyridine.

To achieve blue emission, Ar⁵ may be phenyl and Ar⁶ may be selected from imidazole, triazole or tetrazole.

The compound of formula (I) is preferably a blue light-emitting material.

Examples of bidentate ligands are illustrated below:

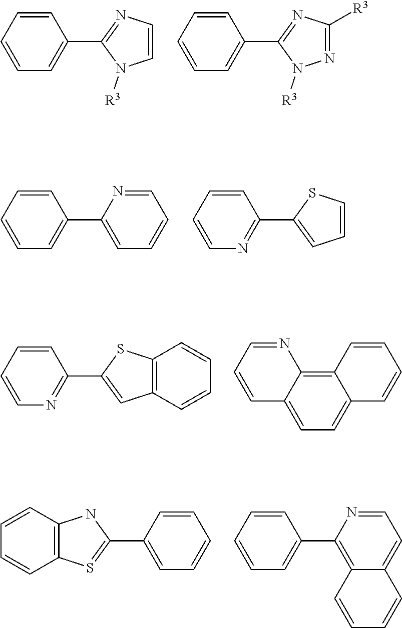

wherein R³ in each occurrence is independently a substituent, preferably a heteroaryl that may be unsubstituted or substituted with one or more substituents; a C₁₋₄₀ hydrocarbyl, preferably C₁₋₂₀ alkyl; unsubstituted aryl, or aryl substituted with one or more substituents. Exemplary substituents of aryl or heteroaryl groups are C₁₋₂₀ alkyl groups. A preferred unsubstituted or substituted aryl group R³ is phenyl. In the case where the bidentate ligand is a ligand L¹, the or each R³ group may be a group of formula (II).

Each of Ar⁵ and Ar⁶ may carry one or more substituents. Two or more of these substituents may be linked to form a ring, for example an aromatic ring.

Other ligands L¹ and L² include diketonates, in particular acetylacetonate (acac); triarylphosphines and pyridine, each of which may be substituted.

L², if present, is different from L¹. L² does not comprise a group of formula (II).

If present, exemplary substituents of L¹, other than the group or groups of formula (II), and L² include fluorine or trifluoromethyl, which may be used to blue-shift the emission of the complex for example as disclosed in WO 02/45466, WO 02/44189, US 2002-117662 and US 2002-182441; alkyl or alkoxy groups, for example C₁₋₂₀ alkyl or alkoxy; C₁₋₂₀ aryl or bi-C₁₋₂₀ aryl, optionally phenyl or biphenyl, wherein the or each aryl group may independently be unsubstituted or substituted with one or more substituents, optionally substituents selected from one or more C₁₋₂₀ alkyl and C₁₋₂₀ alkoxy; and dendrons which may be used to obtain or enhance solution processability of the metal complex, for example as disclosed in WO 02/66552.

A dendron may have optionally substituted formula (XII)

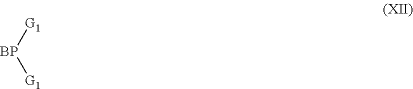

wherein BP represents a branching point for attachment to L1 or L2 and G₁ represents first generation branching groups.

The dendron may be a first, second, third or higher generation dendron. G₁ may be substituted with two or more second generation branching groups G₂, and so on, as in optionally substituted formula (XIIa):

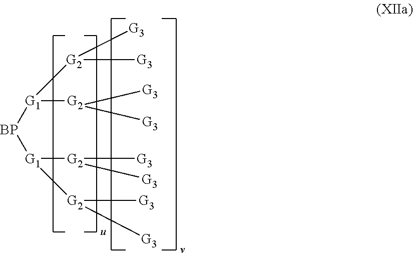

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

A preferred dendron is a substituted or unsubstituted dendron of formula (XIIb):

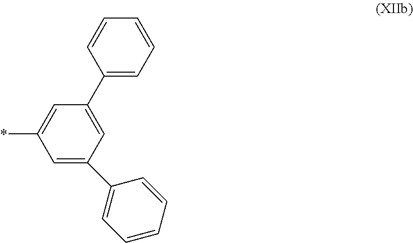 [SMILES: *c1cc(-c2ccccc2)cc(-c2ccccc2)c1]

wherein * represents an attachment point of the dendron to a core.

BP and/or any group G may be substituted with one or more substituents, for example one or more C₁₋₂₀ alkyl or alkoxy groups.

Compounds of formula (I) may be covalently bound to a polymer, for example as a side group, end group or repeat unit of a polymer. The polymer may be a conjugated or non-conjugated polymer.

A compound of formula (I) may be provided as a polymeric repeat unit having two or more linking positions through which the compound is bound to adjacent polymeric repeat units. The two or more linking positions may be provided on any one of or a combination of L¹, X, or (if present) L² or Sp. The linking positions may be provided on a single group selected from L¹, X, L² and Sp or one linking position may be provided on one of L¹, X, L² and Sp and at least one further linking position may be provided on another of L¹, X, L² and Sp. The polymer may be a conjugated polymer. The conjugated polymer may comprise arylene co-repeat units, for example fluorene or phenylene co-repeat units, each of which may be unsubstituted or substituted with one or more substituents, optionally one or more C1-40 hydrocarbyl groups.

A compound of formula (1) may be provided as a side-group or end-group that is bound to a polymer chain through any one of L¹, X, or (if present) L² or Sp.

Exemplary compounds of formula (I) are illustrated below.

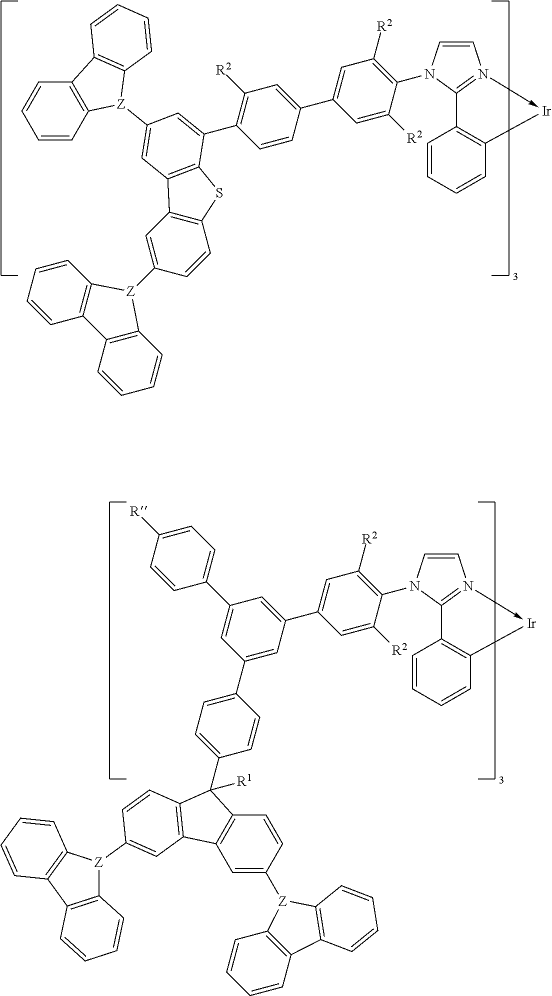

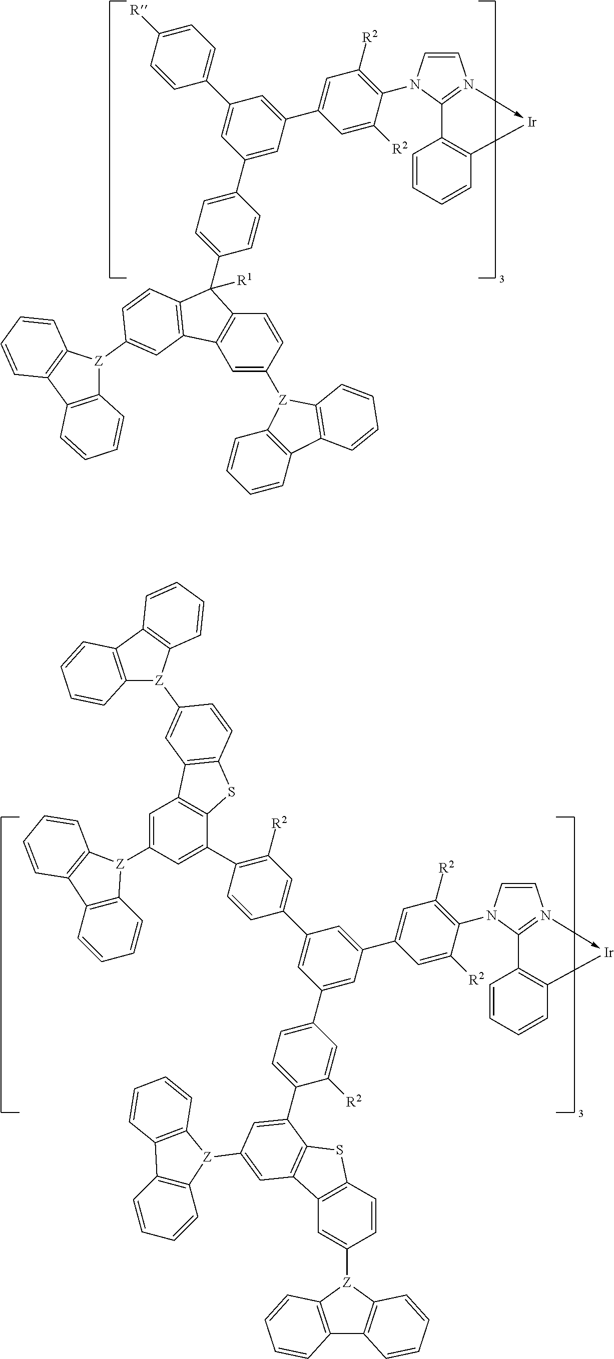

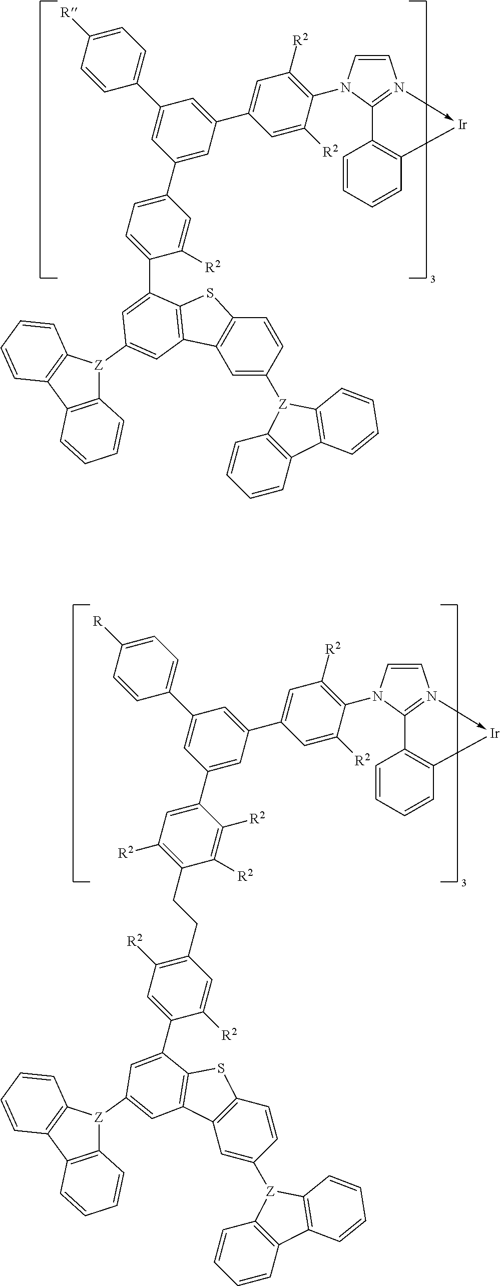

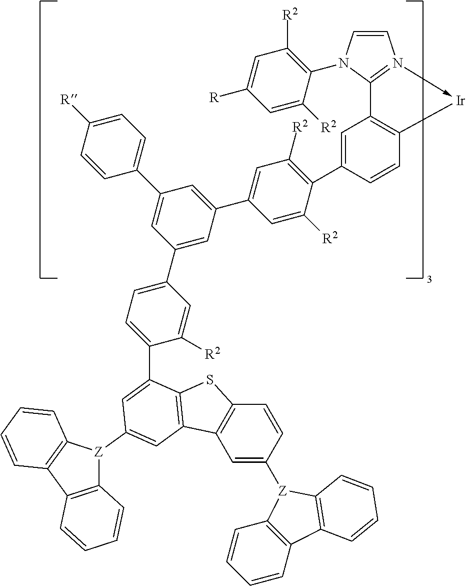

R and R″ are each selected from H, D, aryl or C₁₋₂₀ alkyl

### Z is N or P.

### Charge Transporting and Charge Blocking Layers

A hole transporting layer may be provided between the anode and the light-emitting layer or layers of an OLED.

An electron transporting layer may be provided between the cathode and the light-emitting layer or layers.

A charge-transporting layer or charge-blocking layer may be cross-linked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

If present, a hole transporting layer located between the anode and the light-emitting layers preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

Preferably a hole-transporting layer, more preferably a crosslinked hole-transporting layer, is adjacent to the light-emitting layer containing the compound of formula (I).

If present, an electron transporting layer located between the light-emitting layers and cathode preferably has a LUMO level of around 2.5-3.5 eV as measured by cyclic voltammetry. For example, a layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

A hole-transporting polymer may be substituted with crosslinkable groups as described above that are reacted before forming an overlying layer, such as a light-emitting layer, if the overlying layer is formed by depositing the material of the overlying layer from a solution.

### Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Cathode

The cathode 105 is selected from materials that have a work function allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low work function material and a high work function material such as calcium and aluminium, for example as disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 0.5-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; sodium fluoride; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Formulation Processing

A formulation suitable for forming a light-emitting layer may be formed from the compound of formula (I) and one or more suitable solvents. The formulation is preferably a solution.

Solvents suitable for dissolving the compound of formula (I) include, without limitation, benzenes substituted with one or more C₁₋₁₀ alkyl or C₁₋₁₀ alkoxy groups, for example toluene, xylenes and methylanisoles.

Particularly preferred solution deposition techniques including printing and coating techniques such spin-coating and inkjet printing.

Spin-coating is particularly suitable for devices wherein patterning of the light-emitting layer is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing, screen printing and slot-die coating.

### EXAMPLES

### Compound Example 1

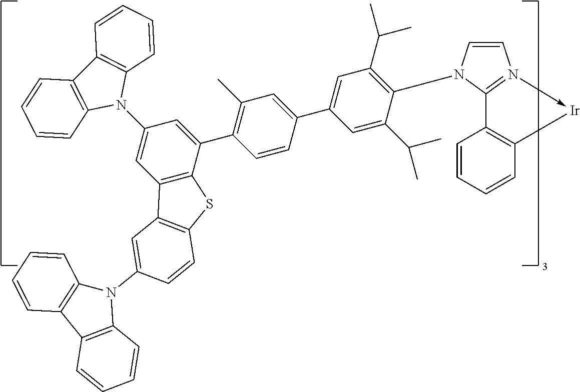

### Compound Example 1

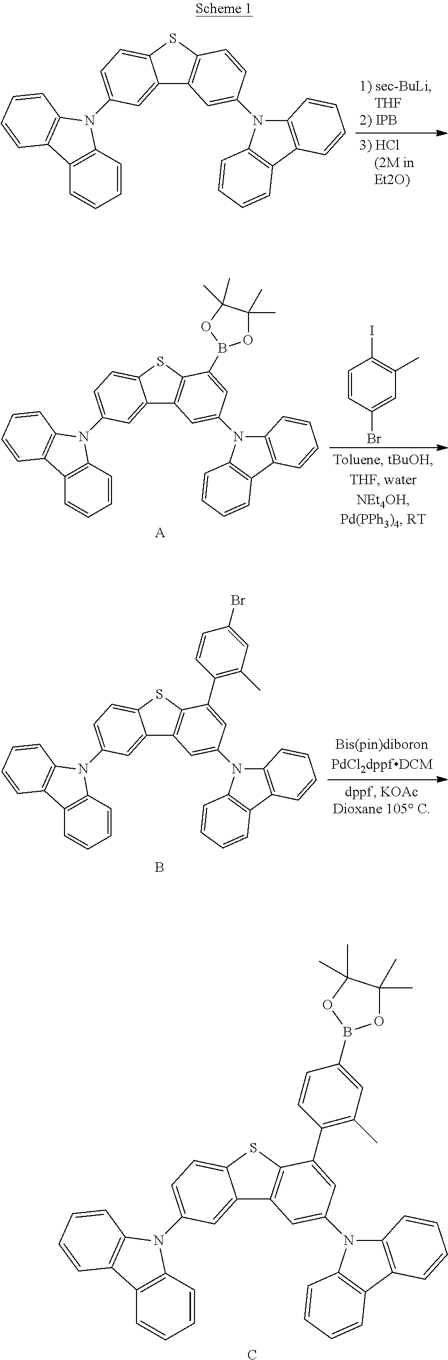

### Intermediate (A)

sec-BuLi (1.4M in cyclohexane, 137.4 ml, 192.4 mmol) was added dropwise to a suspension of (2,8-dibenzothiophenediyl)bis-9H,9′H-carbazole (82.5 g, 160.3 mmol) in tetrahydrofuran (1650 ml) at −74° C. After stirring at −40° C. for 4 hours, the reaction mixture was re-cooled to −74° C. and isopropoxyboronic acid, pinacol ester (45.8 ml, 224.4 mmol) was added dropwise and the mixture allowed to warm to room temperature over night. It was then cooled to −30° C., quenched by the dropwise addition of HCl (2M in diethylether, 88.2 ml, 176.3 mmol), warmed to ambient temperature and concentrated under reduced pressure. The resulting precipitate was removed and the filtrate concentrated under reduced pressure and recrystallized (once from hexane:toluene and twice from acetonitrile:toluene) to give (A) as a white solid (49.6 g, 48% yield) after drying at 50° C. under vacuum.

HPLC: 95.88%.

¹H-NMR (600 MHz, CDCl₃): δ_{H} [ppm] 1.47 (s, 12H), 7.28 (m, 4H), 7.40 (m, 8H), 7.70 (dd, J=1.9 Hz, 8.5 Hz, 1H), 8.15 (m, 6H), 8.29 (d, J=1.7 Hz, 1H), 8.38 (d, J=2.0 Hz, 1H).

### Intermediate (B)

A degassed solution of tetrabutyl ammonium hydroxide (20% w/v in water, 80.5 ml, 109.27 mmol) was added dropwise to a degassed solution of (A) (35.0 g, 4.64 mmol), 5-bromo-2-iodotoluene, (24.33 g, 81.95 mmol), Toluene (328 ml), tert-butanol (219 ml), tetrahydrofuran (164 ml) and water (190 ml), followed by palladium tetrakis (0.631 g, 0.564 mmol). The resulting mixture was stirred for 20 hours at room temperature, under nitrogen, shielded from light. After this time, the aqueous phase was extracted with toluene and the combined organic extracts washed with water and brine, dried over magnesium sulphate and concentrated to dryness under reduced pressure. Purification by column chromatography (hexane:dichloromethane 80:20 to 75:25) and recrystallization (hexane:toluene:ethanol) gave (B) as a white solid (33 g, 88% yield) after drying at 50° C. under vacuum.

HPLC: 94.90%.

¹H-NMR (600 MHz, CDCl₃): δ_{H} [ppm] 2.34 (s, 3H), 7.29 (m, 4H), 7.41 (m, 7H), 7.46 (d, J=8.2 Hz, 2H), 7.52 (dd, J=1.8, 8.2 Hz, 1H), 7.57 (d, J=1.9 Hz, 1H), 7.59 (d, J=1.3 Hz, 1H), 7.71 (dd, J=1.9 Hz, 8.4 Hz, 1H), 8.08 (d, J=8.5 Hz, 1H), 8.15 (m, 4H), 8.34 (d, J=1.9 Hz, 1H), 8.35 (d, J=1.9 Hz, 1H).

### Intermediate (C)

1,1′-Bis(diphenylphosphino)ferrocene palladium dichloride dichloromethane adduct (0.315 g, 0.39 mmol) and 1,1′-bis(diphenylphosphino)ferrocene (0.214 g, (0.39 mmol) were added to a degassed solution of (B) (33.0 g, 48.27 mmol) and bis(pinacolato)diboron (13.5 g, 53.10 mmol) in anhydrous 1,4-dioxane (330 ml). Potassium acetate (14.2 g, 144.81 mmol) was added and the mixture stirred at 115° C. over night. The mixture was cooled to room temperature, filtered through a silica/florisil/celite plug and concentrated under reduced pressure. Purification by column chromatography (hexane:dichloromethane 70:30 to 20:80) and recrystalization (acetonitrile:dicholomethane) gave (C) as a white solid (23.9 g, 70.5% yield) after drying at 50° C. under vacuum.

HPLC: 99.86%.

¹H-NMR (600 MHz, CDCl₃): δ_{H} [ppm] 1.40 (s, 12H), 2.37 (s, 3H), 7.29 (m, 4H), 7.41 (m, 6H), 7.48 (d, J=8.2 Hz, 2H), 7.53 (d, J=7.4 Hz, 1H), 7.60 (d, J=1.8 Hz, 1H), 7.70 (dd, J=1.9 Hz, 8.4 Hz, 1H), 7.83 (d, J=7.5 Hz, 1H), 7.88 (s, 1H), 8.07 (d, J=8.5 Hz, 1H), 8.15 (m, 4H), 8.32 (d, J=1.8 Hz, 1H), 8.35 (d, J=1.8 Hz, 1H).

### Compound Example 1

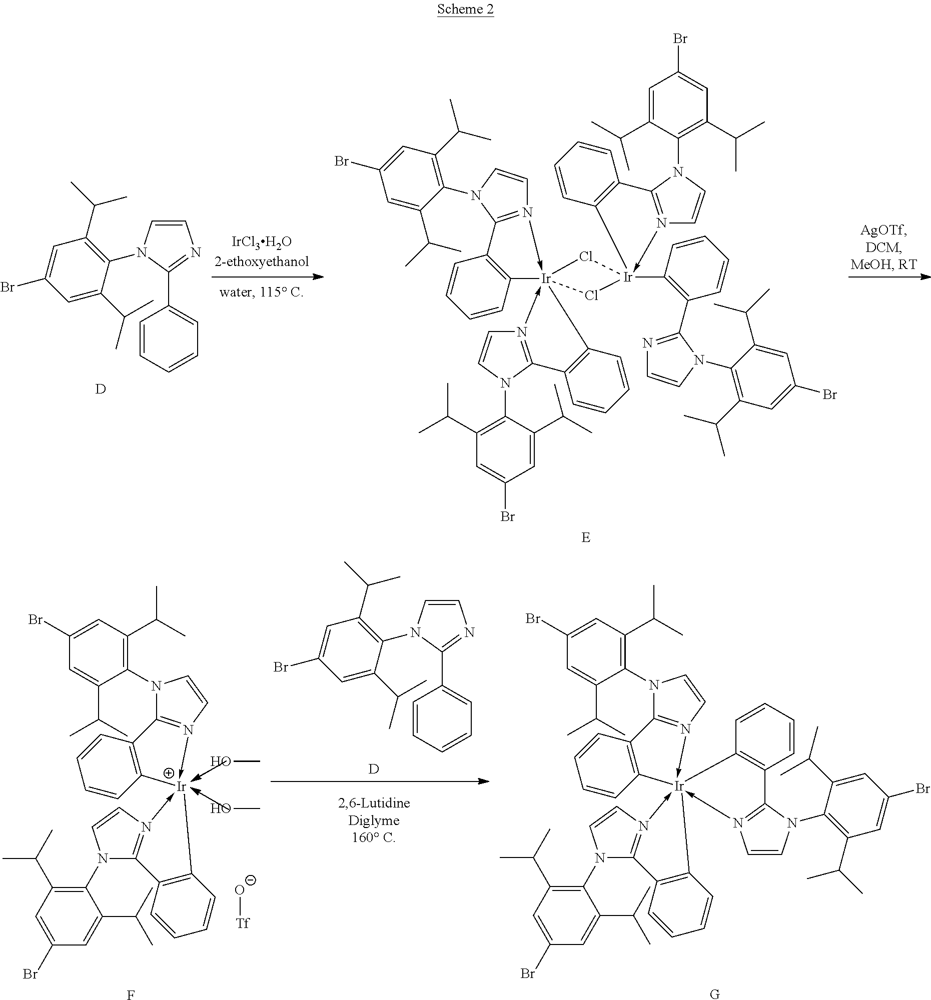

### Intermediate (E)

A degassed mixture of (D) (21.0 g, 54.78 mmol), iridium trichloride trihydrate (8.4 g, 23.81 mmol), 2-ethoxyethanol (315 ml) and water (105 ml) was stirred for 22 hours at 115° C., while shielded from light. After cooling to room temperature, water (250 ml) was added and the reaction stirred for a further 2 hours as this temperature. The resulting slurry was filtered, washed with water (3×250 ml) and methanol (100 ml) and dried at 50° C. under vacuum to give (E) as a pale yellow solid (21.1 g, 89% yield).

### Intermediate (F)

A degassed solution of silver triflate (5.6 g, 21.79 mmol) in methanol (120 ml) was added to a degassed solution of (E) (21.1 g, 10.63 mmol) in dichloromethane (390 ml) while shielding from light, and the reaction stirred at room temperature for 20 hours. After filtration through a celite plug and concentration under reduced pressure, the crude material was triturated with water, filtered and dried at 50° C. under vacuum to give (F) as yellow solid (18.6 g, 75% yield).

### Intermediate (G)

A degassed solution of 2,6-lutidine (18.5 ml, 159.31 mmol) was added to a suspension of (F) (18.6 g, 15.93 mmol) and (D) (10.7 g, 27.88 g) in diglyme (250 ml) while shielding from light. After stirring at 160° C. for 36 hours, the reaction was cooled to ambient temperature, and diluted with water (400 ml) and methanol (100 ml). The resulting solid was dissolved in dichloromethane and filtered through a silica/florisil plug (hexane:dichloromethane 80:20 to 40:60). Fractions containing the product were concentrated to remove dichloromethane and the resulting hexane suspension filtered to give (G) as a yellow solid (16.1 g, 75% yield) after drying at 50° C. under vacuum.

HPLC: 99.95%.

¹H-NMR (600 MHz, THF-d8): δ_{H} [ppm] 0.88 (d, J=6.8 Hz, 9H), 0.96 (d, J=6.8 Hz, 9H), 1.00 (d, J=6.8 Hz, 9H), 1.22 (d, J=6.8 Hz, 9H), 2.33 (sept, 3H), 2.73 (sept, 3H), 6.20 (d, J=7.7 Hz, 3H), 6.36 (td, J=1.0 Hz, 7.5 Hz, 3H), 6.48 (td, J=1.0 Hz, 7.4 Hz, 3H), 6.74 (d, J=7.4 Hz, 3H), 6.76 (d, J=1.3 Hz, 3H), 6.98 (d, J=1.3 Hz, 3H), 7.52 (d, J=2.1 Hz, 3H), 7.54 (d, J=2.1 Hz, 3H).

### Compound Example 1

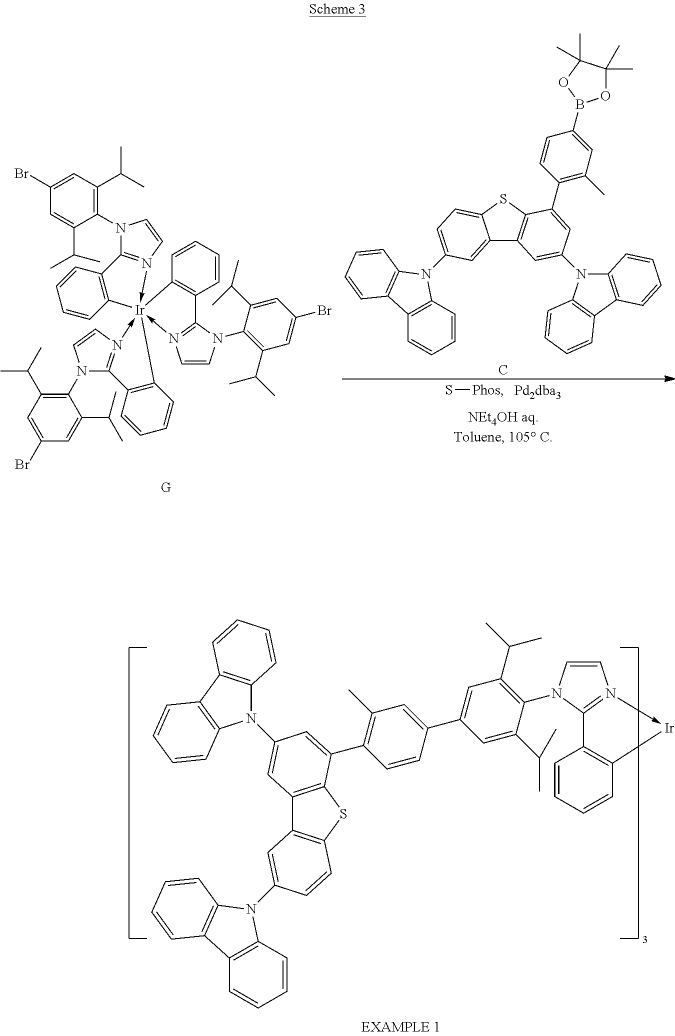

Tris(dibenzylidene acetone) dipalladium (0.0462 g, 0.05 mmol) and 2-dicyclohexylphosphino-2′,6′-dimethoxybiphenyl (0.0454 g, 0.10 mmol) were added to a degassed solution of (G) (4.5 g, 3.36 mmol) and (C) (8.35 g, 11.43 mmol) in toluene (90 ml) while shielding from light. A degassed solution of tetra butyl ammonium hydroxide (20% w/v in water, 29.7 ml, 40.3 mmol) was added at 105° C. and the reaction mixture stirred overnight at this temperature. After cooling, the organic phase was washed with water, dried over magnesium sulphate and concentrated to dryness under reduced pressure. Purification by filtration through a silica/florisil plug (hexane:ethyl acetate 80:20 and hexane:dichloromethane 80:20) following by recrystalization (hexane:n-butyl acetate), hot titration (acetonitrile:n-butyl acetate:toluene) and repeated recrystalization (toluene:acetonitrile) gave Example 1 as a yellow solid (7.28 g, 74% yield) after drying at 50° C. under vacuum.

HPLC: 99.68%.

¹H-NMR (600 MHz, THF-d8): δ_{H} [ppm] 1.05 (d, J=6.8 Hz, 9H), 1.12 (d, J=6.8 Hz, 9H), 1.18 (d, J=6.8 Hz, 9H), 1.37 (d, J=6.8 Hz, 9H), 2.52 (m, 12H), 2.92 (sept, 3H), 6.37 (d, J=7.1 Hz, 3H), 6.41 (t, J=7.3 Hz, 3H), 6.54 (td, J=1.3 Hz, 7.3 Hz, 3H), 6.86 (d, J=7.6 Hz, 3H), 6.90 (d, J=1.1 Hz, 3H), 7.10 (d, J=1.1 Hz, 3H), 7.24 (m, 12H), 7.37 (m, 12H), 7.44 (d, J=8.2 Hz, 6H), 7.55 (d, J=8.2 Hz, 6H), 7.70 (d, J=7.9 Hz, 3H), 7.75 (d, J=1.9 Hz, 6H), 7.78 (m, 6H), 7.80 (d, J=1.9 Hz, 3H), 7.85 (s, 3H), 8.16 (m, 12H), 8.23 (d, J=8.4 Hz, 3H), 8.68 (d, J=1.9 Hz, 6H).

### Compound Example 2

### Compound Example 2

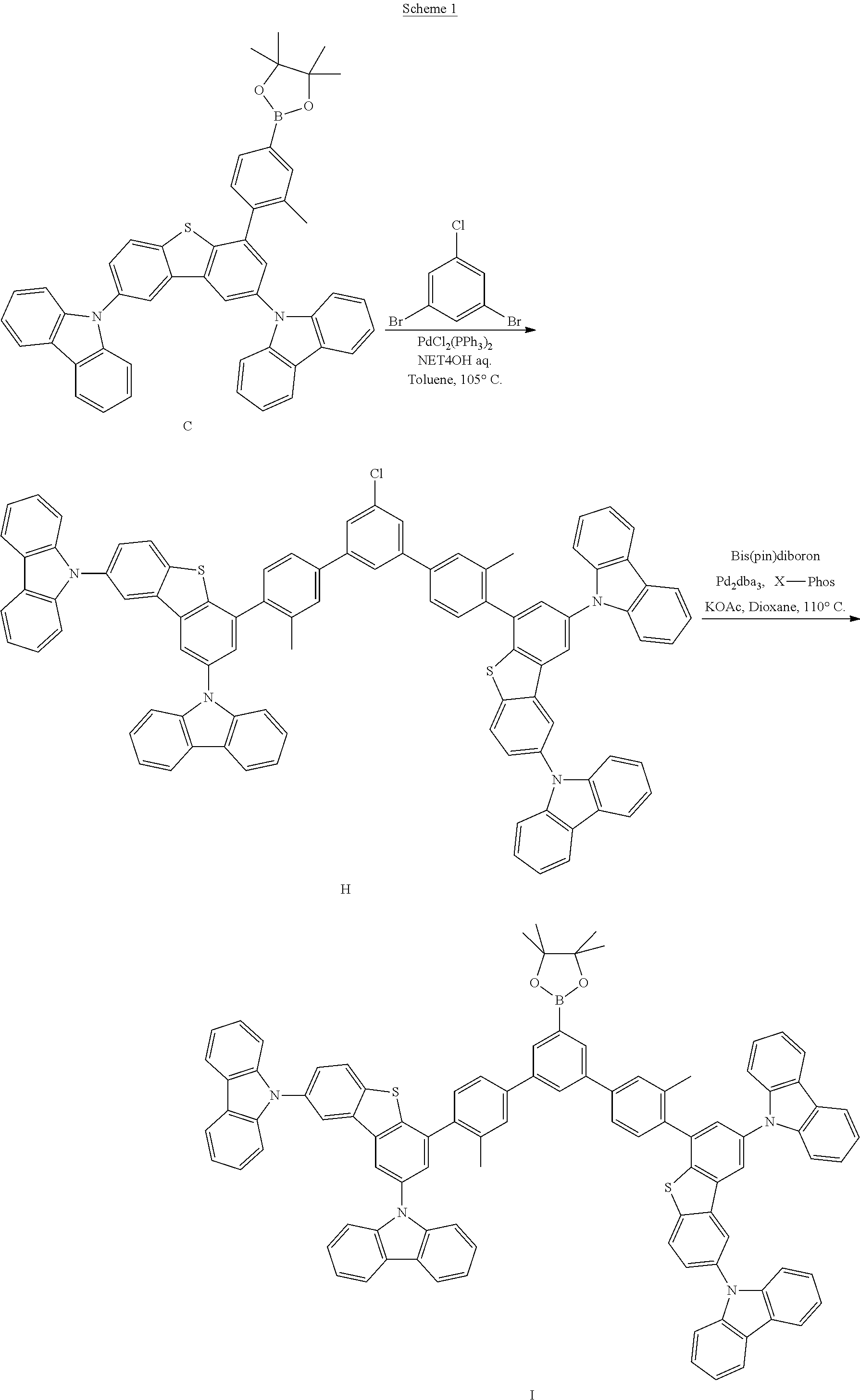

### Intermediate (H)

A degassed solution of tetra butyl ammonium hydroxide (20% w/v in water, 57.8 ml, 78.52 mmol) was added to a degassed solution of (C) (14.56 g, 19.93 mmol) and 1,3-dibromo-5-chlorobenzene (2.65 g, 9.82 mmol) in toluene (300 ml) while stirring, shielding from light, at 105° C. followed by palladium tetrakis (0.138 g, 0.196 mmol). After 4 hours the reaction mixture was cooled to ambient temperature, the aqueous phase extracted with toluene and the combined organic phases washed with water, brine, dried over magnesium sulphate and concentrated to dryness under reduced pressure. Purification by filtration through a silica/florisil/celite plug followed by titration (hexane) gave (H) as a white solid (12.78 g, 96% yield) after drying at 50° C. under vacuum.

HPLC: 95.94%.

¹H-NMR (600 MHz, CDCl₃): δ_{H} [ppm] 2.47 (s, 6H), 7.30 (m, 8H), 7.43 (m, 12H), 7.51 (d, J=8.2 Hz, 4H), 7.67 (m, 6H), 7.72 (m, 6H), 7.89 (m, 1H), 8.10 (d, J=8.5 Hz, 2H), 8.16 (d, J=7.8 Hz, 8H), 8.36 (d, J=1.9 Hz, 2H), 8.38 (d, J=1.9 Hz, 2H).

### Intermediate (I)

Tris(dibenzylidene acetone) dipalladium (0.164 g, 0.179 mmol) and 2-(Dicyclohexylphosphino)-2′,4′,6′-triisopropylbiphenyl (0.170 g, 0.357 mmol) were added to a degassed solution of (H) (11.78 g, 8.94 mmol) and bis(pinacolato)diboron (2.72 g, 10.72 mmol) in anhydrous dioxane (120 ml) while stirring shielded from light, followed by a potassium acetate (2.64 g, 26.81 mmol). After stirring for 8 hours at 110° C., the reaction mixture was cooled to ambient temperature and the crude product was purified by filtration through a silica/florisil/celite plug and recrystallization (acetonitrile:toluene) to give (I) as a white solid (10.72 g, 85% yield) after drying at 50° C. under vacuum.

HPLC: 93.23%.

¹H-NMR (600 MHz, CDCl₃): δ_{H} [ppm] 1.44 (s, 12H), 2.47 (s, 6H), 7.30 (t, J=7.4 Hz, 8H), 7.43 (m, 12H), 7.52 (d, J=8.2 Hz, 4H), 7.64 (d, J=7.8 Hz, 2H), 7.68 (d, J=1.9 Hz, 2H), 7.72 (dd, J=1.9 Hz, 8.4 Hz, 2H), 7.75 (dd, J=1.3 Hz, 7.9 Hz, 2H), 7.79 (s, 2H), 8.10 (d, J=8.5 Hz, 2H), 8.12 (m, 1H), 8.16 (d, J=7.8 Hz, 8H), 8.19 (d, J=1.7 Hz, 2H), 8.36 (d, J=1.9 Hz, 2H), 8.37 (d, J=1.9 Hz, 2H).

### Compound Example 2

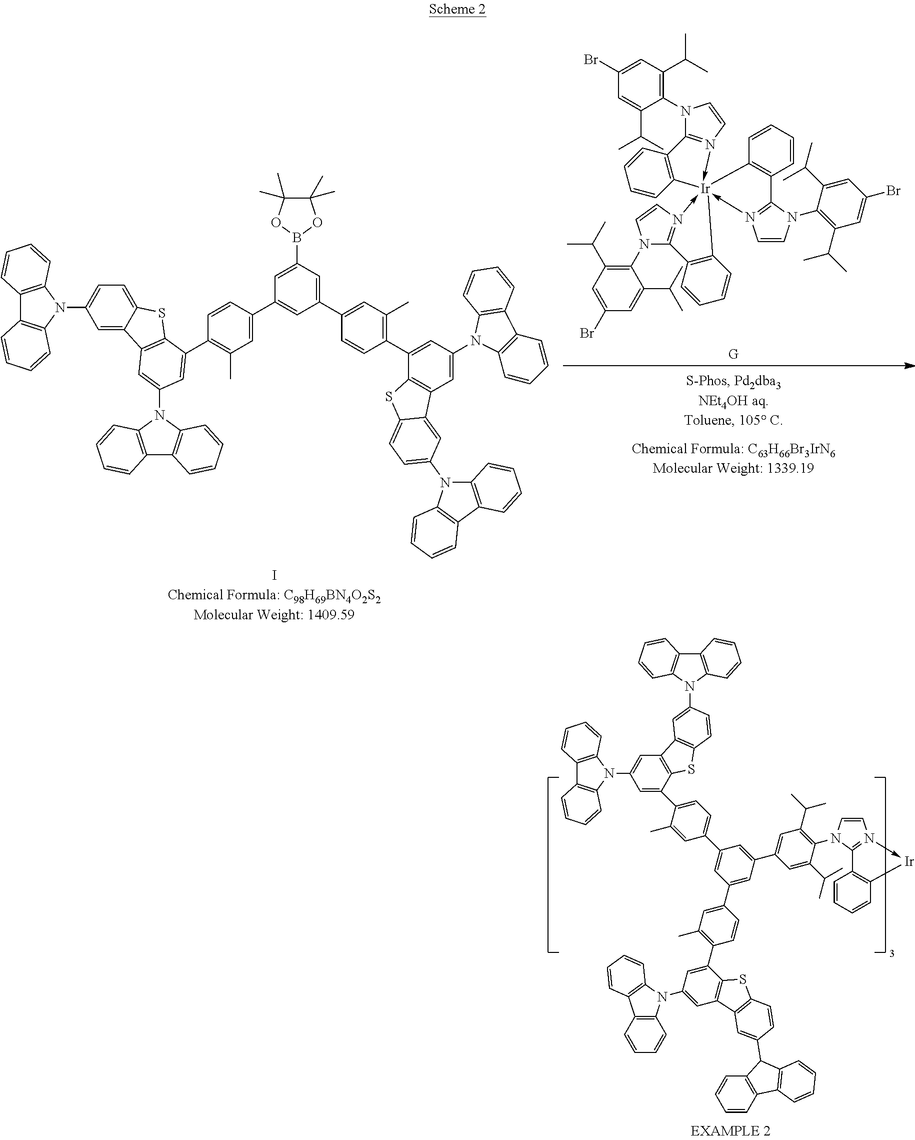

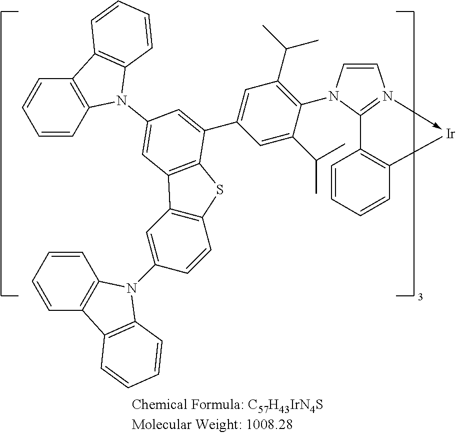

Tris(dibenzylidene acetone) dipalladium (0.0268 g, 0.029 mmol), and 2-dicyclohexylphosphino-2′,6′-dimethoxybiphenyl (0.0240 g, 0.059 mmol) were added to a degassed solution of (G) (2.61 g, 1.95 mmol) and (I) (10.2 g, 6.44 mmol) in toluene (100 ml) while stirring, shielded from light at 105° C., followed by a degassed solution of tetra butyl ammonium hydroxide (20% w/v in water, 17.2 ml, 23.42 mmol). After 4 hours, the reaction mixture was cooled to ambient temperature, the aqueous phase extracted with toluene and the combined organic layers were washed with water, dried over magnesium sulphate and concentrated to dryness under reduced pressure. Purification by column chromatography (tetrahydrofuran:water 90:10, and dichloromethane:hexane 40:60) and repeated precipitation (acetonitrile:toluene) gave the product as a yellow solid (2.10 g, 22% yield) after drying at 50° C. under vacuum.

HPLC: 99.52%.

¹H-NMR (600 MHz, THF-d8): δ_{H} [ppm] 1.07 (d, J=6.8 Hz, 9H), 1.15 (d, J=6.8 Hz, 9H), 1.20 (d, J=6.8 Hz, 9H), 1.39 (d, J=6.8 Hz, 9H), 2.52 (s, 18H), 2.56 (sept, 3H), 2.95 (sept, 3H), 6.44 (m, 6H), 6.56 (m, 3H), 6.88 (d, J=7.6 Hz, 3H), 6.92 (s, 3H), 7.10 (s, 3H), 7.23 (t, J=7.4 Hz, 24H), 7.36 (m, 24H), 7.44 (d, J=8.2 Hz, 12H), 7.55 (d, J=8.2 Hz, 12H), 7.73 (d, J=7.9 Hz, 6H), 7.76 (d, J=1.9 Hz, 6H), 7.78 (dd, J=1.9 Hz, 8.5 Hz, 6H), 7.86 (dd, J=1.3 Hz, 13.8 Hz, 6H), 7.90 (dd, J=0.9 Hz, 7.8 Hz, 6H), 7.96 (s, 6H), 8.11 (d, J=1.1 Hz, 6H), 8.15 (m, 27H), 8.27 (d, J=8.4 Hz, 6H), 8.68 (d, J=1.7 Hz, 12H).

### Compound Example 3

### Compound Example 3

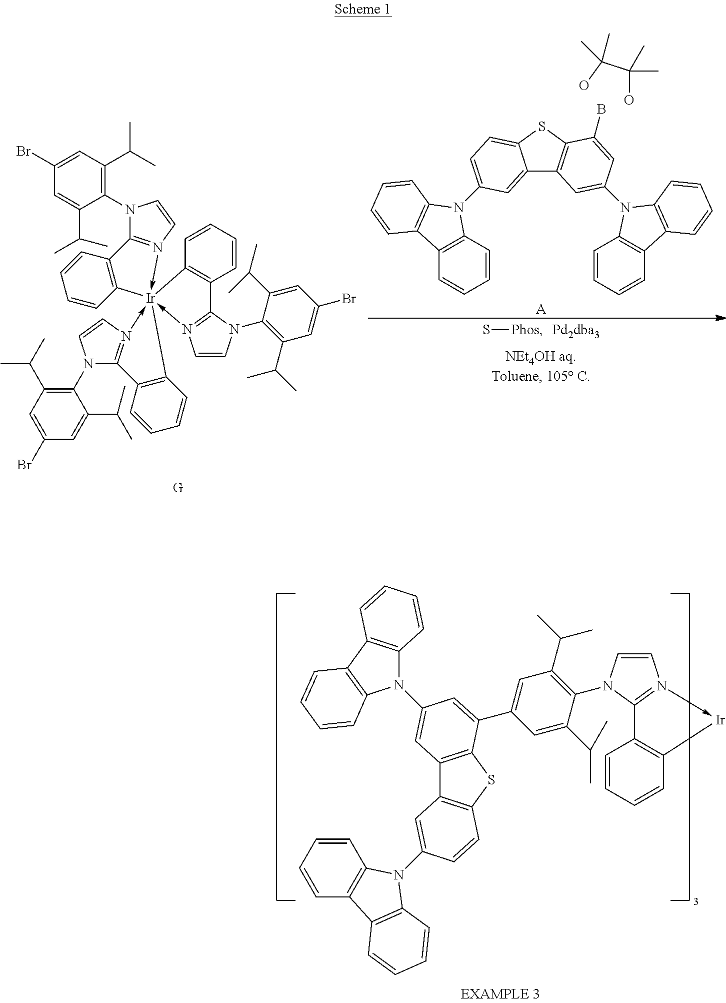

Tris(dibenzylidene acetone) dipalladium (2.4 mg, 0.0026 mmol) and 2-dicyclohexylphosphino-2′,6′-dimethoxybiphenyl (2.1 mg, 0.0052 mmol) were added to a degassed solution of (G) (0.23 g, 0.17 mmol) and (A) (0.40 g, 0.62 mmol) in toluene (10 ml) while stirring, shielded from light. The reaction mixture was heated to 105° C. and a solution of degassed tetra butyl ammonium hydroxide (20% w/v in water, 1.5 ml, 2.06 mmol) was added and the reaction mixture stirred at this temperature overnight. TLC analysis after this time showed consumption of the starting material and the mixture was cooled to ambient temperature, the organic phase washed with water, dried over magnesium sulphate and concentrated to dryness under reduced pressure. Purification by column chromatography (amine column dichloromethane:hexane 30:70 and reverse phase tetrahydrafuran:acetonitrile 40:60 to 100) gave the product as a yellow solid (0.305 g, 68% yield) after drying at 50° C. under vacuum.

HPLC: 99.2%

¹H-NMR (600 MHz, THF-d8): δ_{H} [ppm] 1.06 (d, J=6.8 Hz, 9H), 1.12 (d, J=6.8 Hz, 9H), 1.18 (d, J=6.8 Hz, 9H), 1.39 (d, J=6.8 Hz, 9H), 2.57 (sept, 3H), 2.97 (sept, 3H), 6.39 (d, J=7.3 Hz, 3H), 6.43 (t, J=7.2 Hz, 3H) 6.55 (td, J=1.2 Hz, 7.4 Hz, 3H), 6.87 (d, J=7.4 Hz, 3H), 6.93 (d, J=1.2 Hz, 3H), 7.21 (d, J=1.1 Hz, 3H), 7.24 (q, J=7.8 Hz, 12H), 7.37 (m, 12H), 7.45 (d, J=8.2 Hz, 6H), 7.53 (d, J=8.2 Hz, 6H), 7.82 (dd, J=2.0 Hz, 8.4 Hz, 3H), 7.97 (m, 6H), 8.03 (d, J=1.9 Hz, 3H), 8.15 (d, J=7.9 Hz, 6H), 8.17 (d, J=7.8 Hz, 6H), 8.33 (d, J=8.5 Hz, 3H), 8.68 (m, 6H).

### Photoluminescence Measurements

A film of a composition of Compound Examples 1, 2 or 3 (5 wt %) and Host 1 (95 wt %) was cast from solution.

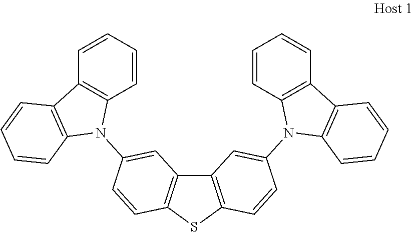 [SMILES: c1ccc2c(c1)c1ccccc1n2-c1ccc2sc3ccc(-n4c5ccccc5c5ccccc54)cc3c2c1]

Measurements are set out in Table 1. Photoluminescent quantum yield (PLQY) of the films was measured using an integrating sphere, Hamamatsu, Model: C9920-02. CIE coordinates were measured using a Minolta CS200 ChromaMeter.

Scheme 1

| Example | PLQY/% | CIEx | CIEy |
|---|---|---|---|
| Example 1 | 85.5 | 0.189 | 0.401 |
| Example 2 | 84.5 | 0.197 | 0.422 |
| Example 3 | 79.1 | 0.192 | 0.409 |

### Device Example 1

A blue organic light-emitting device having the following structure was prepared:

### ITO/HIL/HTL/LEL/Cathode

wherein ITO is an indium-tin oxide anode; HIL is a hole-injecting layer comprising a hole-injecting material, HTL is a hole-transporting layer, and LEL is a light-emitting layer containing a compound of formula (I) and a host material.

A substrate carrying ITO was cleaned using UV/Ozone. A hole injection layer was formed to a thickness of about 35 nm by spin-coating a formulation of a hole-injection material. A hole transporting layer was formed to a thickness of about 22 nm by spin-coating a crosslinkable hole-transporting polymer and crosslinking the polymer by heating at 180° C. The light-emitting layer was formed by spin-coating Host 1 (55 wt %) and Compound Example 1 (45 wt %). An electron-transporting layer was formed on the light-emitting layer. A cathode was formed on the electron-transporting layer of a first layer of sodium fluoride of about 2 nm thickness, a layer of aluminium to a thickness of about 100 nm and a layer of silver to a thickness of about 100 nm.

The crosslinkable hole-transporting polymer comprises 50 mol % of phenylene repeat units substituted with crosslinkable groups and 50 mol % of a diamine repeat unit as described in WO 2005/049546.

The electron-transporting layer was formed by spin-coating an electron-transporting polymer as described in WO 2012/133229.

### Comparative Device 1

A device was prepared as described for Device Example 1 except that the light-emitting layer was formed by spin-coating Comparative Emitter 1 (25 wt %), illustrated below, and Host 1 (75 wt %).

The host: emitter weight ratio of Device Example 1 is greater than that of Device Example 1 because Example 1 carries Host 1 as a substituent and Comparative Compound 1 does not.

The amounts of Host 1 used with Compound Example 1 (55 wt %) and used with Comparative Compound 1 (75 wt %) were selected so that the metal core: host ratio is the same.

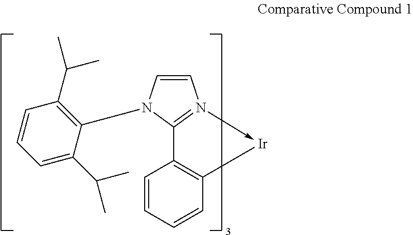

### Device Example 2

A device was prepared according to Device Example 1 except that the hole transport layer was heated at 230° C.

### Comparative Device 2

A device was prepared according to Device Example 2 except that the light-emitting layer was formed by spin-coating Comparative Emitter 1 (25 wt %) and Host 1 (75 wt %).

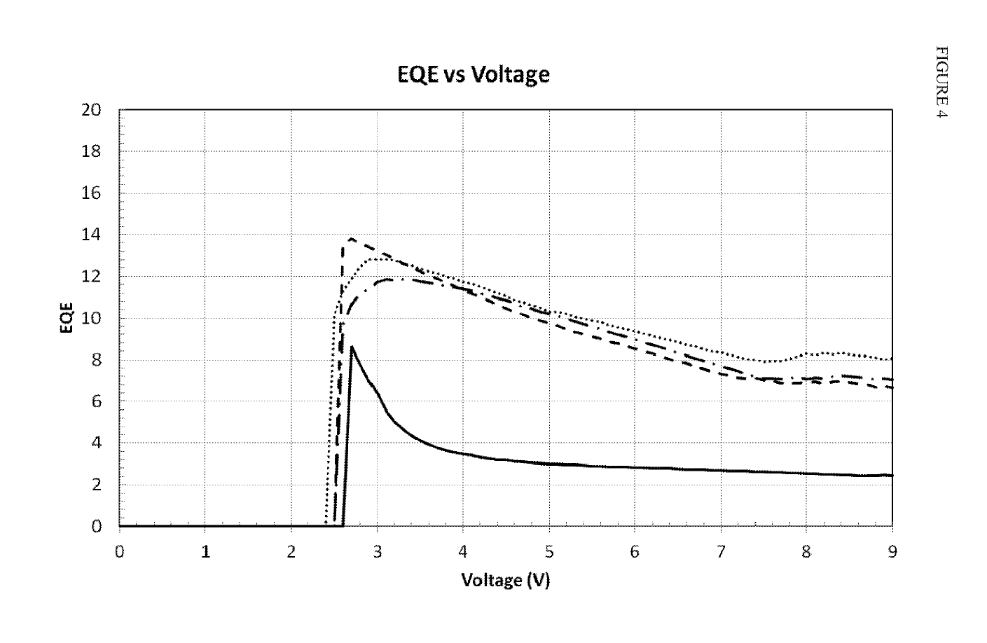

With reference to FIG. 3, current density is similar for Device Examples 1 and 2 and Comparative Devices 1 and 2.

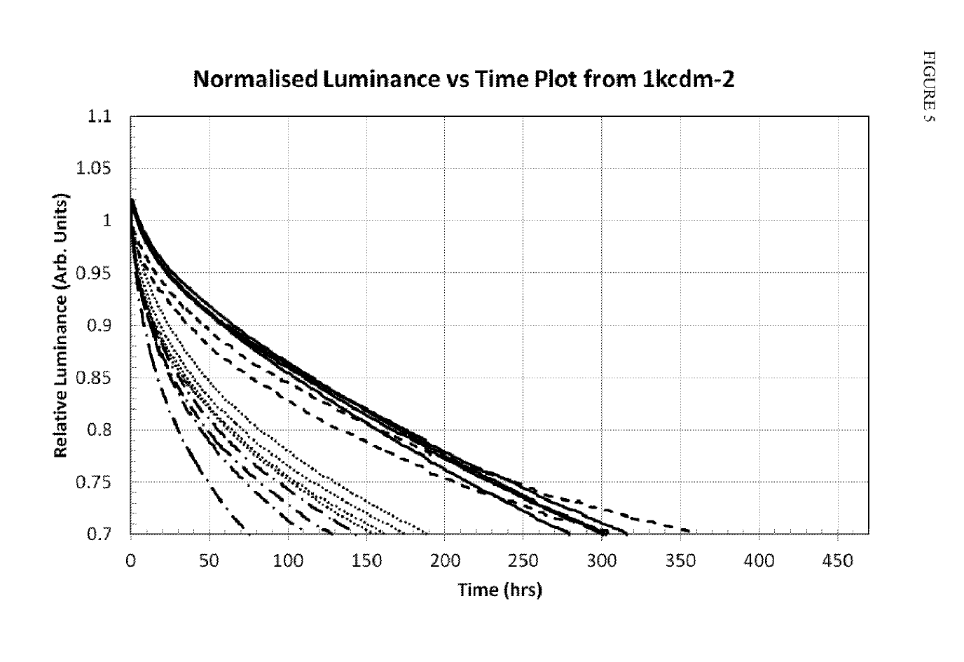

With reference to FIG. 4, external quantum efficiency of Comparative Device 2, in which the hole-transporting layer is heated at 230° C. falls sharply as compared to Comparative Device 1 in which the hole-transporting layer is heated at 180° C., whereas external quantum efficiency remains similar for Device Examples 1 and 2.

With reference to FIG. 5, lifetime of Device Example 1 is similar to that of Comparative Device 1.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A phosphorescent metal complex of formula (I):
ML¹ₙL²ₘ (I)
wherein:
M is a transition metal;
L¹ is a ligand substituted with at least one group of formula (II):
*-(Sp)ₐ-(X)_{b} (II)
wherein Sp is a spacer group; a is 0 or 1; b is 1 if a is 0 and b is at least 1 if a is 1;
and X independently in each occurrence is a group of formula (IIIa), (IIIb) or (IIIc): 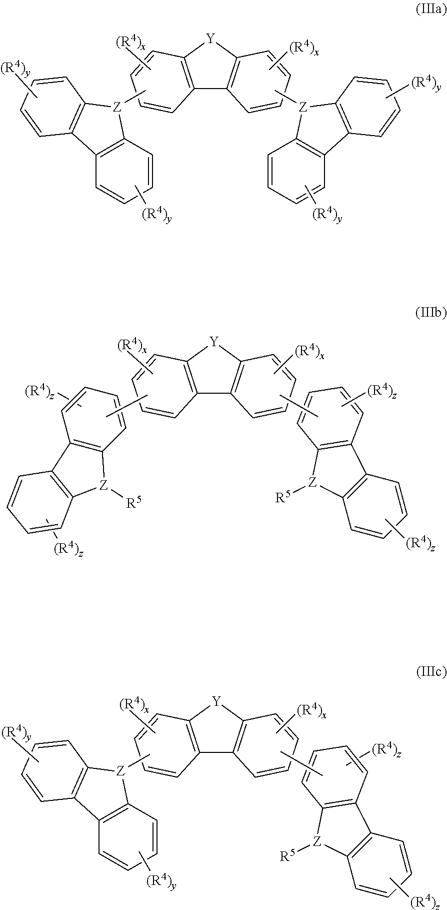
wherein Y is selected from O, S, a substituted carbon atom; and a substituted silicon atom; Z in each occurrence is independently selected from N and P; R⁴ independently in each occurrence is a substituent; R⁵ independently in each occurrence is H or a substituent; x independently in each occurrence is 0, 1, 2 or 3; y in each occurrence is independently 0, 1, 2, 3 or 4; and z in each occurrence is independently 0, 1, 2, 3 or 4;
L² independently in each occurrence is a ligand that may be unsubstituted or substituted with one or more substituents;
n is at least 1; and
m is 0 or a positive integer.

2. A phosphorescent metal complex according to claim 1 wherein M is iridium.

3. A phosphorescent metal complex according to claim 1, wherein n is 2 or 3 and m is 0.

4. A phosphorescent metal complex according to claim 1, wherein the or each L¹ is substituted with one or more substituents in addition to the at least one group of formula (II).

5. A phosphorescent metal complex according to claim 1, wherein the or each L¹ is a CAN cyclometalating bidentate ligand.

6. A phosphorescent metal complex according to claim 5 wherein the or each L¹ is phenylimidazole.

7. A phosphorescent metal complex according to claim 1 wherein a is 1 and Sp is a dendritic group comprising a branching point and at least two branching groups.

8. A phosphorescent metal complex according to claim 1 wherein a is 1 and Sp comprises at least one aryl or heteroaryl group spacing L¹ from X.

9. A phosphorescent metal complex according to claim 8 wherein Sp comprises a chain of at least two aryl or heteroaryl groups spacing L¹ from X.

10. A phosphorescent metal complex according to claim 8, wherein the or each aryl or heteroaryl group spacing L¹ from X is a phenylene group that may be unsubstituted or substituted with one or more substituents.

11. An organic light-emitting device comprising an anode, a cathode and a light-emitting layer between the anode and the cathode wherein the light-emitting layer comprises a phosphorescent metal complex according to claim 1.

12. An organic light emitting device according to claim 11 wherein the light-emitting layer consists of the phosphorescent metal complex.

13. An organic light-emitting device according to claim 11, wherein the device further comprises a hole-transporting layer between the anode and the light-emitting layer.

14. A formulation comprising a phosphorescent metal complex according to claim 1, and at least one solvent.

15. A method of forming an organic light-emitting device according to claim 13 wherein the light-emitting layer is formed by depositing a formulation comprising a phosphorescent metal complex of formula (I):
ML¹ₙL²ₘ (I)
wherein:
M is a transition metal;
L¹ is a ligand substituted with at least one group of formula (II):
*-(Sp)ₐ-(X)_{b} (II)
wherein Sp is a spacer group; a is 0 or 1; b is 1 if a is 0 and b is at least 1 if a is 1;
and X independently in each occurrence is a group of formula (IIIa), (IIIb) or (IIIc): 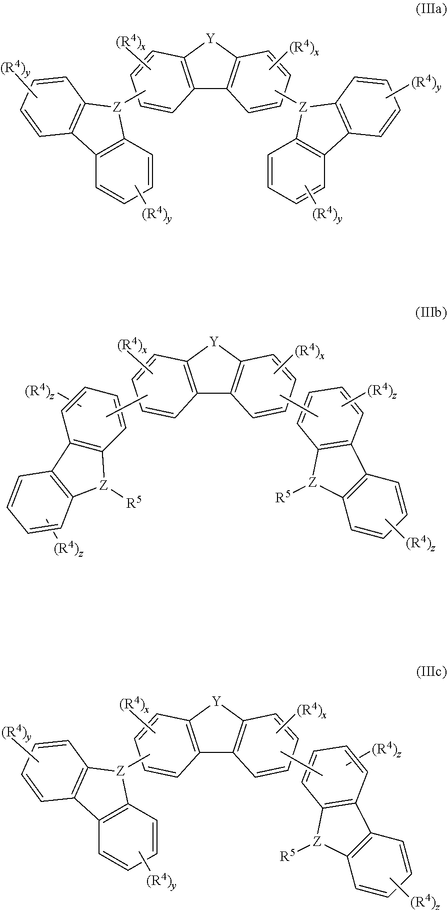
wherein Y is selected from O, S, a substituted carbon atom; and a substituted silicon atom; Z in each occurrence is independently selected from N and P; R⁴ independently in each occurrence is a substituent; R⁵ independently in each occurrence is H or a substituent; x independently in each occurrence is 0, 1, 2 or 3; y in each occurrence is independently 0, 1, 2, 3 or 4; and z in each occurrence is independently 0, 1, 2, 3 or 4;
L² independently in each occurrence is a ligand that may be unsubstituted or substituted with one or more substituents;
n is at least 1; and
m is 0 or a positive integer, and at least one solvent onto the hole-transporting layer and evaporating the solvent.

16. A method according to claim 15 wherein the hole-transporting layer is thermally crosslinked prior to formation of the light-emitting layer.

17. An organic light-emitting device comprising an anode, a cathode and a light-emitting layer between the anode and the cathode, wherein the light-emitting layer consists essentially of a phosphorescent light-emitting material comprising a hole-transporting light-emitting metal complex and an electron-transporting substituent bound to the light-emitting metal complex.
